(19) United States
(12) Patent Application Publication
(10) Pub. No.: US 2026/0173983 A1
(43) Pub. Date: Jun. 18, 2026

(54) SEMICONDUCTOR DEVICE

(71) Applicant: Mitsubishi Electric Corporation, Tokyo (JP)

(72) Inventor: Takeshi HIGASHIHATA, Tokyo (JP)

(73) Assignee: Mitsubishi Electric Corporation, Tokyo (JP)

(21) Appl. No.: 19/128,555

(22) PCT Filed: Jan. 30, 2023
(86) PCT No.: PCT/JP2023/002837

§ 371 Date: May 8, 2025

(51) Int. Cl. H10W 90/00; H10W 40/22; H10W 40/77

(52) U.S. Cl. CPC H10W 90/754; H10W 40/22; H10W 40/778; H10W 90/736

(57) ABSTRACT

Provided is a semiconductor device that can reduce a partial discharge that may occur between a screw that fixes a case to a heat sink and a high-voltage portion and that can enhance the reliability. The semiconductor device includes a heat sink and a case. The heat sink holds the semiconductor element. The case houses the semiconductor element held upward of the heat sink. A first screw hole is formed in a side surface of the heat sink. A second screw hole in communication with the first screw hole is formed in the case. The case is fastened to the heat sink through a screw screwed into the first and second screw holes.

### TECHNICAL FIELD

The present disclosure relates to a semiconductor device.

### BACKGROUND ART

Power modules including semiconductor devices for power control have structures in each of which a heat sink and a case are fastened through screws. For example, in a semiconductor device disclosed in Patent Document 1, tapping screws made of a metal fasten a resin case from below through holes of a heat sink to above screw holes. This fixes the resin case to the heat sink.

### PRIOR ART DOCUMENT

### Patent Document

Patent Document 1: Japanese Patent Application Laid-Open No. 2006-32392

### SUMMARY

### Problem to be Solved by the Invention

When the insulation performance of the resin case around the holes through which the tapping screws pass is insufficient in the structure disclosed in Patent Document 1, a local discharge (hereinafter referred to as a partial discharge) may occur between a high-voltage portion sealed inside the resin case and the tapping screws.

The present disclosure has an object of providing a semiconductor device that can reduce a partial discharge that may occur between a screw that fixes a case to a heat sink and a high-voltage portion and that can enhance the reliability to solve the problem.

### Means to Solve the Problem

A semiconductor device according to the present disclosure includes a heat sink and a case. The heat sink holds a semiconductor element. The case houses the semiconductor element held upward of the heat sink. A first screw hole is formed in a side surface of the heat sink. A second screw hole in communication with the first screw hole is formed in the case. The case is fastened to the heat sink through a screw screwed into the first and second screw holes.

### Effects of the Invention

The present disclosure provides a semiconductor device that can reduce a partial discharge that may occur between a screw that fixes a case to a heat sink and a high-voltage portion in a power module and that can enhance the reliability.

The object, features, aspects, and advantages of this disclosure will become more apparent from the following detailed description and the accompanying drawings.

### BRIEF DESCRIPTION OF DRAWINGS

FIG. 1 is a cross-sectional view illustrating a structure of a semiconductor device according to Embodiment 1.

FIG. 2 is a cross-sectional view illustrating a part of a structure of a semiconductor device according to Embodiment 2.

FIG. 3 is a plan view illustrating a part of a structure of a heat sink of a semiconductor device.

FIG. 4 is a cross-sectional view illustrating a structure of a semiconductor device according to Embodiment 3.

FIG. 5 is a cross-sectional view illustrating a part of a structure of a semiconductor device.

FIG. 6 is a plan view illustrating a part of a structure of a heat sink of a semiconductor device.

FIG. 7 is a plan view illustrating a part of a structure of a heat sink of a semiconductor device according to Embodiment 4.

FIG. 8 is a plan view illustrating the part of the structure of the heat sink of the semiconductor device according to Embodiment 4.

FIG. 9 is a cross-sectional view illustrating a structure of a semiconductor device according to Embodiment 5.

FIG. 10 is a cross-sectional view illustrating a structure of a semiconductor device according to Embodiment 6.

### DESCRIPTION OF EMBODIMENTS

### Embodiment 1

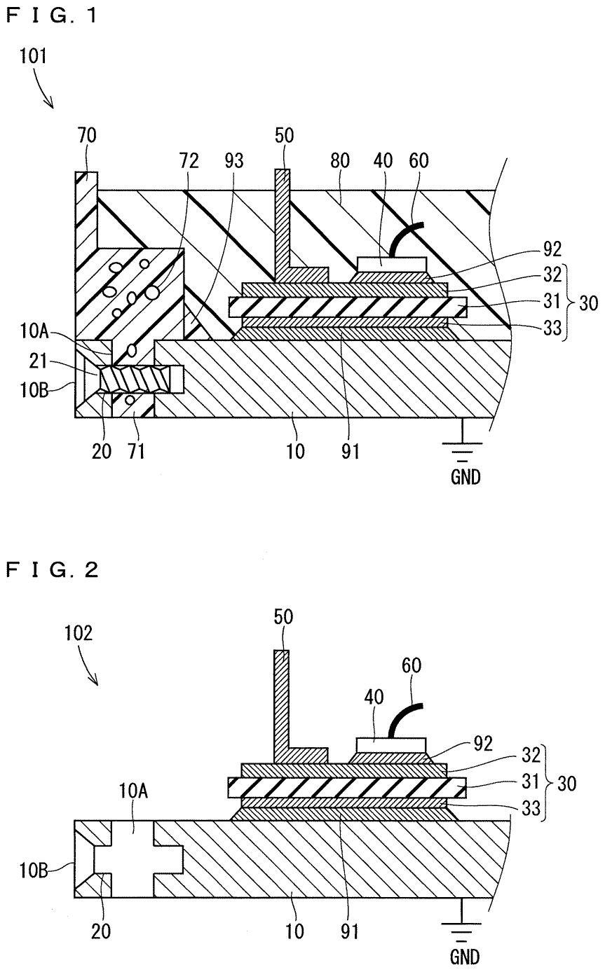

FIG. 1 is a cross-sectional view illustrating a structure of a semiconductor device 101 according to Embodiment 1. The semiconductor device 101 includes a heat sink 10, a screw hole 20, an insulating substrate 30, a semiconductor element 40, a terminal 50, a metal wire 60, a case 70, and a sealant 80.

The heat sink 10 holds the semiconductor element 40 disposed on the insulating substrate 30. The heat sink 10 is, for example, a plate made of a metal such as Cu or Al, or a plate made of an Al-SiC composite material. The heat sink 10 includes a position defining portion 10A.

The position defining portion 10A defines a position of the case 70 in the heat sink 10. The position defining portion 10A according to Embodiment 1 includes a through hole penetrating an upper surface and a lower surface of the heat sink 10.

The screw hole 20 is formed in a side surface 10B of the heat sink 10. The screw hole 20 extends inward from the side surface 10B of the heat sink 10. The screw hole 20 is a hole for fastening the case 70 to the heat sink 10 through a tapping screw 21. The screw hole 20 penetrates a protrusion 71 of the case 70 which mates with the position defining portion 10A. In other words, the screw hole 20 includes a first screw hole formed in the side surface 10B of the heat sink 10, and a second screw hole formed in communication with the first screw hole in the case 70.

The insulating substrate 30 includes an insulating layer 31, a circuit surface pattern 32, and a heat dissipating surface pattern 33. The insulating layer 31 has insulating properties, and is made of, for example, a ceramic. Examples of the ceramic include AlN, Si₃N₄, and Al₂O₃. The circuit surface pattern 32 is disposed on the upper surface of the insulating layer 31. The heat dissipating surface pattern 33 is disposed on the lower surface of the insulating layer 31. The circuit surface pattern 32 and the heat dissipating surface pattern 33 are made of a metal such as Cu or Al. The heat dissipating surface pattern 33 is bonded to the heat sink 10 through a bonding material 91 such as solder, a brazing filler metal, or a sintered material. In other words, the heat sink 10 holds the insulating substrate 30.

The semiconductor element 40 is bonded to the circuit surface pattern 32 of the insulating substrate 30 through a bonding material 92. The bonding material 92 has conductivity. The bonding material 92 is, for example, solder. The semiconductor element 40 is also referred to as a semiconductor chip. The semiconductor element 40 is made of, for example, a semiconductor such as Si, or a wide bandgap semiconductor such as SiC, GaN, Ga₂O₃, or diamond. The semiconductor element 40 is, for example, a power semiconductor element or a control integrated circuit (IC) for controlling the power semiconductor element. The semiconductor element 40 is, for example, an insulated-gate bipolar transistor (IGBT), a metal-oxide-semiconductor field effect transistor (MOSFET), or a Schottky barrier diode. Alternatively, the semiconductor element 40 may be a reverse-conducting IGBT (RC-IGBT) in which an IGBT and a free-wheeling diode are formed in one semiconductor substrate.

The terminal 50 is a conductor configured to be connectable to an external circuit disposed outside the semiconductor device 101. The terminal 50 is, for example, a metal frame obtained by processing, into a predetermined shape, a plate made of a metal such as CU. Although FIG. 1 illustrates the terminal 50 as a component separated from the case 70, the terminal 50 may be integrally mounted on the case 70. The terminal 50 includes a first end and a second end. The first end corresponds to a lower end in FIG. 1, and is bonded to the circuit surface pattern 32 of the insulating substrate 30. The first end may be, for example, bonded to an electrode (not illustrated) of the semiconductor element 40 through a wire (not illustrated). The first end of the terminal 50 is bonded to the circuit surface pattern 32 or the electrode of the semiconductor element 40 by ultrasonic bonding or solder. The second end corresponds to a upper end in FIG. 1, and is led to an outside of the case 70 and the sealant 80. The second end is connectable to an external circuit.

The metal wire 60 connects two components from among the electrode of the semiconductor element 40, the first end of the terminal 50, and the circuit surface pattern 32 of the insulating substrate 30.

The case 70 has a hollow frame shape. Although the cross-sectional view of FIG. 1 omits the illustration of a structure to the right of the case 70, the case 70 has a rectangular frame in a plan view. The case 70 is disposed on the heat sink 10 to enclose the upper surface of the heat sink 10. The case 70 houses, for example, the insulating substrate 30 and the semiconductor element 40 in an internal space enclosed by the frame, that is, inside the frame shape. The case 70 is made of, for example, a resin. The resin is, for example, polyphenylene sulfide (PPS).

The case 70 mates with the position defining portion 10A of the heat sink 10. The case 70 according to Embodiment 1 includes a protrusion 71 that mates with the through hole of the heat sink 10 which is included in the position defining portion 10A. The protrusion 71 is disposed at the bottom of the case 70.

The case 70 is fastened to the heat sink 10 through the tapping screw 21 screwed into the screw hole 20 of the heat sink 10. The end of the tapping screw 21 penetrates the protrusion 71 of the case 70 from the outside of the case 70. The end of the tapping screw 21 is located inside the screw hole 20 formed in the heat sink 10. In other words, the end of the tapping screw 21 is neither exposed to the internal space of the case 70 filled with the sealant 80 nor stays inside the case 70.

Furthermore, the case 70 is bonded to the heat sink 10 through a silicone adhesive 93. As such, the case 70 is bonded to the heat sink 10 through the silicone adhesive 93 and the tapping screw 21.

The sealant 80 fills the internal space enclosed by the frame of the case 70. The sealant 80 seals the upper surface of the heat sink 10, the insulating substrate 30, the semiconductor element 40, a part of the terminal 50, and the metal wire 60. The sealant 80 is a hardening material such as a silicone resin or an epoxy resin.

In a first manufacturing process of the semiconductor device 101, the screw hole 20 of the heat sink 10 (a first screw hole) is formed by shaving a material of the heat sink 10 when the tapping screw 21 is screwed into the heat sink 10. Similarly, the screw hole 20 of the protrusion 71 of the case 70 (a second screw hole) is formed by shaving the resin of the case 70 when the tapping screw 21 is screwed into the case 70. In this first manufacturing process, the material of the tapping screw 21 needs to be harder than those of the heat sink 10 and the case 70.

In a second manufacturing process of the semiconductor device 101, the screw hole 20 is formed in advance, and the tapping screw 21 is screwed into the screw hole 20. Although the screw hole 20 may be threaded in advance, the screw hole 20 need not be threaded in advance when the material of the tapping screw 21 is harder than those of the heat sink 10 and the case 70. In the former case, a normal screw can be used instead of the tapping screw 21. Furthermore, since the material of the tapping screw 21 is normally harder than that of the case 70, the screw hole 20 of the protrusion 71 of the case 70 (second screw hole) need not be formed in advance. FIG. 1 illustrates the second manufacturing process.

After the case 70 is bonded to the heat sink 10, the liquid sealant 80 is injected into the internal space of the case 70. Then, a curing treatment cures the sealant 80.

In the aforementioned structure, the end of the tapping screw 21 is not exposed to the internal space enclosed by the frame of the case 70. Furthermore, the end of the tapping screw 21 is not located inside a resin portion that forms the case 70, that is, inside the frame. The end of the tapping screw 21 fits inside the heat sink 10. Thus, even when the resin portion of the case 70 includes a defective portion 72 such as a void or a crack, a partial discharge between a high-voltage portion of the semiconductor device 101 that is a power module and the tapping screw 21 is reduced. As such, even when the insulation performance of the case 70 is insufficient, a decrease in the reliability of the semiconductor device 101 is prevented.

In summary, the semiconductor device 101 according to Embodiment 1 includes the heat sink 10 and the case 70. The heat sink 10 holds the semiconductor element 40. The case 70 houses the semiconductor element 40 held upward of the heat sink 10. The first screw hole of the screw hole 20 is formed in the side surface 10B of the heat sink 10. The second screw hole of the screw hole 20 in communication with the first screw hole of the screw hole 20 is formed in the case 70. The case 70 is fastened to the heat sink 10 through the screw screwed into the first and second screw holes of the screw hole 20. The screw according to Embodiment 1 is the tapping screw 21.

The semiconductor device 101 reduces a partial discharge that may occur between a screw that fixes the case 70 to the heat sink 10 and a high-voltage portion. Consequently, the semiconductor device 101 with high reliability is obtained.

Patent Document 1 discloses a structure in which a vertical screw hole in a case is a through hole and a sealant fills a top of the through hole as a structure of reducing a partial discharge. In such a structure, however, the sealant to be cured may leak outside the heat sink through a space between the through hole and the tapping screw in the manufacturing process. The leakage of the sealant worsens the manufacturing yield of the semiconductor device.

The semiconductor device 101 according to Embodiment 1 does not include any through hole penetrating the internal space of the case 70 toward the outside. The semiconductor device 101 reduces the partial discharge without any external leakage of the sealant 80.

Furthermore, since the case 70 mates with the position defining portion 10A of the heat sink 10, the case 70 is easily positioned when the case 70 is bonded to the heat sink 10 in the manufacturing process. Consequently, a jig for fixing the positions of the heat sink 10 and the case 70 becomes unnecessary, and the workability will be improved.

The semiconductor device 101 includes, as the semiconductor element 40, a power semiconductor element made of a wide bandgap semiconductor. The enhancement of the reliability of the semiconductor device 101 allows operations at high temperatures, increases in breakdown voltage, and low losses in a power conversion device such as an inverter on which the semiconductor device 101 is to be mounted.

### Embodiment 2

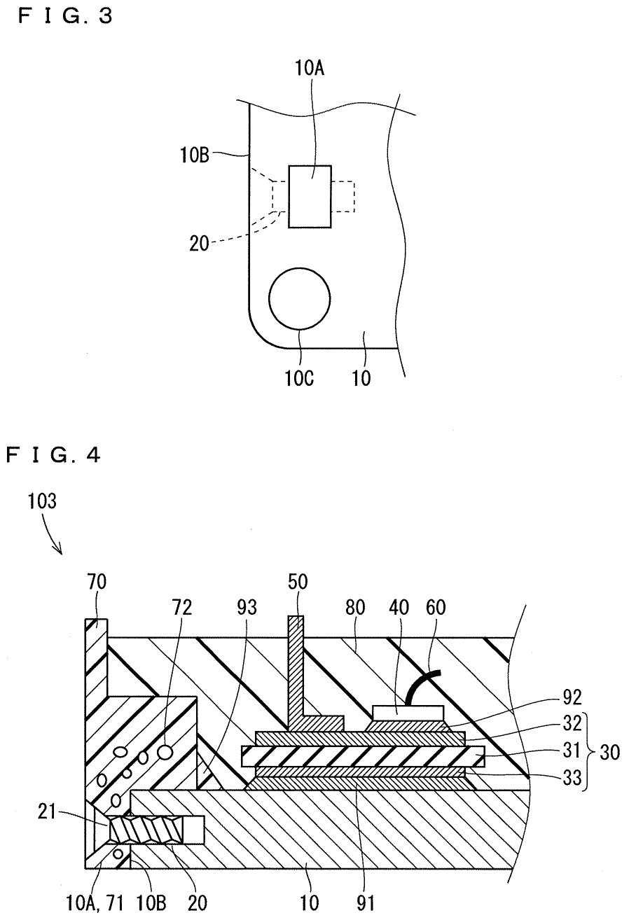

FIG. 2 is a cross-sectional view illustrating a part of a structure of a semiconductor device 102 according to Embodiment 2. FIG. 3 is a plan view illustrating a part of a structure of the heat sink 10 of the semiconductor device 102.

The semiconductor device 102 according to Embodiment 2 is the one whose manufacturing process is the second manufacturing process described in Embodiment 1, and the illustration shows that the screw hole 20 (first screw hole) and the position defining portion 10A are formed in advance in the heat sink 10. 10C denotes a screw hole for fixing the heat sink 10 to an installation target object of the semiconductor device 102.

The case 70 is fastened to the heat sink 10 through the tapping screw 21 screwed into the screw hole 20, similarly to Embodiment 1. The end of the tapping screw 21 fits inside the heat sink 10, and is not exposed to the internal space of the case 70 filled with the sealant 80.

This Embodiment 2 produces the same advantages as those according to Embodiment 1 previously described.

### Embodiment 3

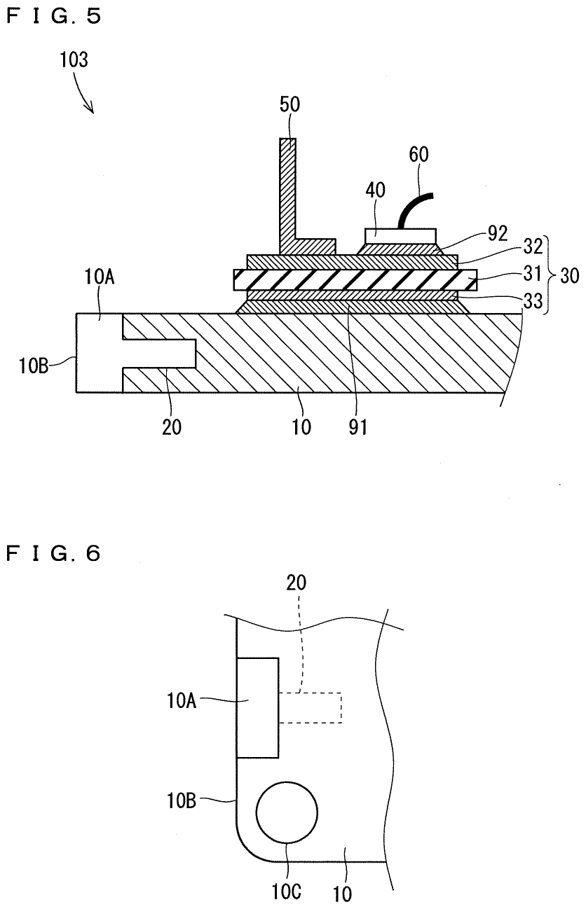

FIG. 4 is a cross-sectional view illustrating a structure of a semiconductor device 103 according to Embodiment 3. FIG. 5 is a cross-sectional view illustrating a part of the structure of the semiconductor device 103. FIG. 6 is a plan view illustrating a part of a structure of the heat sink 10 of the semiconductor device 103. The semiconductor device 103 according to Embodiment 3 differs from the semiconductor device 101 according to Embodiment 1 in the structure of the position defining portion 10A of the heat sink 10 and the case 70 that mates with the position defining portion 10A.

The position regulating portion 10A includes a cutout portion disposed in a periphery of the heat sink 10. The cutout portion is formed in the side surface 10B of the heat sink 10 to overlap an opening of the screw hole 20.

The case 70 includes the protrusion 71 that mates with the cutout portion. The case 70 is fastened to the heat sink 10 through the tapping screw 21 screwed into the screw hole 20.

The end of the tapping screw 21 penetrates the protrusion 71 of the case 70 from the outside of the case 70. The end of the tapping screw 21 fits inside the heat sink 10, and is not exposed to the internal space of the case 70 filled with the sealant 80.

The first manufacturing process or the second manufacturing process described in Embodiment 1 is applicable to a manufacturing process of the semiconductor device 103.

As described above, since the case 70 mates with the position defining portion 10A of the heat sink 10, the case 70 is easily positioned when the case 70 is bonded to the heat sink 10 in the manufacturing process. Consequently, a jig for fixing the positions of the heat sink 10 and the case 70 becomes unnecessary, and the workability will be improved.

### Embodiment 4

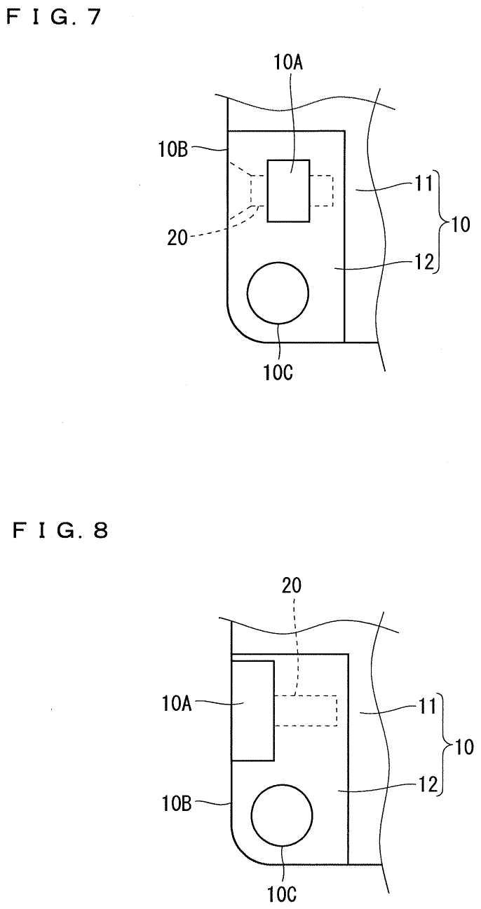

FIGS. 7 and 8 are plan views each illustrating a part of a structure of the heat sink 10 of a semiconductor device according to Embodiment 4. As illustrated in FIGS. 7 and 8, the semiconductor device according to Embodiment 4 differs from the semiconductor device 101 according to Embodiment 1 and the semiconductor device 103 according to Embodiment 3 in the structure of the heat sink 10.

The heat sink 10 according to Embodiment 4 includes a first region 11 and a second region 12. The first region 11 is made of AlSiC. The second region 12 is made of Al. The semiconductor element 40 is disposed to overlap the first region 11 in a plan view. The screw hole 20 and the position defining portion 10A are formed in the second region 12.

The case 70 is fastened to the heat sink 10 through the tapping screw 21 screwed into the screw hole 20. The material of the tapping screw 21 is harder than Al, that is, the material of the heat sink 10 in the second region 12.

The first manufacturing process or the second manufacturing process described in Embodiment 1 is applicable to a manufacturing process of a semiconductor device. The first manufacturing process is easily applicable by using Al as a material of the heat sink 10 in the second region 12 which is softer than a general material of the tapping screw 21.

Since the semiconductor element 40 in the semiconductor device according to Embodiment 4 is disposed above the first region 11 made of AlSiC, the heat dissipation properties will be improved. Since the screw hole 20 is located in the second region 12 made of Al softer than AlSiC, formation and fastening of the screw hole 20 using the tapping screw 21 are easy. In other words, the heat sink 10 in which the screw hole 20 is formed in advance need not be prepared before the screw hole 20 is fastened using the tapping screw 21. Thus, the processing man-hour in fabricating the heat sink 10 is reduced.

### Embodiment 5

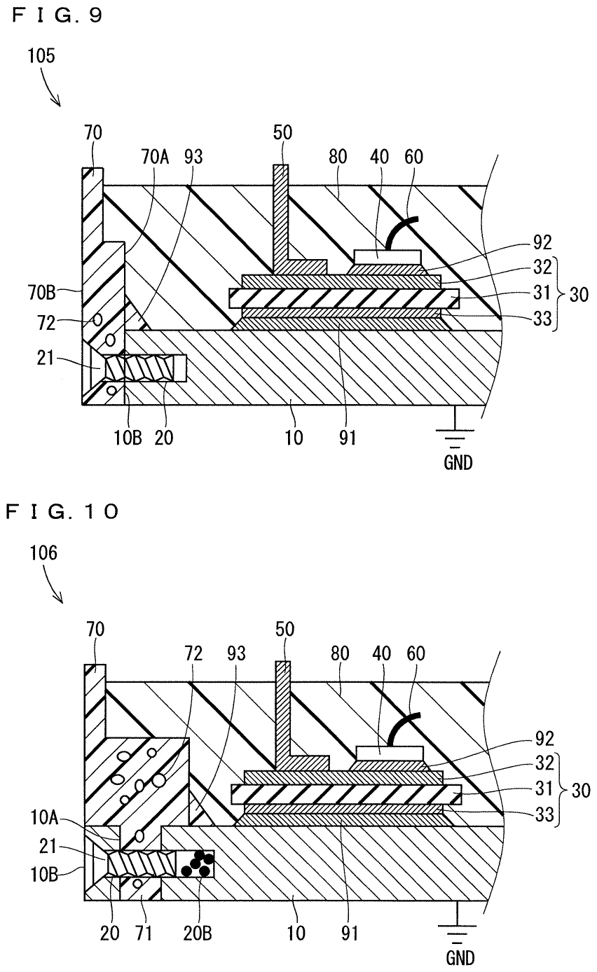

FIG. 9 is a cross-sectional view illustrating a structure of a semiconductor device 105 according to Embodiment 5. The semiconductor device 105 according to Embodiment 5 differs from the semiconductor device 101 according to Embodiment 1 in the structure of the heat sink 10 and the case 70.

The case 70 is disposed in contact with the side surface 10B in which an inner surface 70A of the frame of the case 70 is formed as the periphery of the heat sink 10. For example, the case 70 may be in contact with the entirety of the side surface 10B that is at least one of the four side surfaces of the heat sink 10.

The case 70 is fastened to the heat sink 10 through the tapping screw 21 screwed from an external surface 70B of the frame of the case 70 into the screw hole 20. The end of the tapping screw 21 penetrates the case 70 from the external surface 70B of the frame of the case 70. The end of the tapping screw 21 is located inside the screw hole 20 of the heat sink 10. The end of the tapping screw 21 is not exposed to the internal space of the case 70 filled with the sealant 80.

The first manufacturing process or the second manufacturing process described in Embodiment 1 is applicable to a manufacturing process of the semiconductor device 105.

This Embodiment 5 produces the same advantages as those according to Embodiment 1 previously described.

### Embodiment 6

FIG. 10 is a cross-sectional view illustrating a structure of a semiconductor device 106 according to Embodiment 6. Embodiment 6 is particularly a preferred embodiment when the second manufacturing process described in Embodiment 1 is applied.

The screw hole 20 includes a hollow portion at its deepest portion. For example, the end of the tapping screw 21 and a margin at the deepest portion of the screw hole 20 that is formed in advance in the heat sink 10 form the hollow portion.

The heat sink 10 includes, inside the screw hole 20, shavings 20B made of the same material as that of the heat sink 10 or the case 70. For example, the shavings 20B are confined in the hollow portion at the deepest portion of the screw hole 20. These shavings 20B are generated in the manufacturing process of the semiconductor device 106.

The second manufacturing process described in Embodiment 1 is applied to a manufacturing process of the semiconductor device 106. The screw hole 20 has an opening in the side surface 10B of the heat sink 10.

Next, the tapping screw 21 is screwed into the screw hole 20, with the protrusion 71 of the case 70 mating with the position defining portion 10A. When the tapping screw 21 is screwed, the materials of the heat sink 10 and the protrusion 71 of the case 70 are shaved to generate shavings made of the same material as that of the case 70 and shavings made of the same material as that of the heat sink 10.

The end of the tapping screw 21 does not reach the deepest portion of the screw hole 20. Thus, the shavings 20B generated in the process of forming the screw hole 20 are confined in the hollow portion at the end of the screw hole 20.

The end of the tapping screw 21 fits inside the heat sink 10, and is not exposed to the internal space of the case 70 filled with the sealant 80. Furthermore, since the screw hole 20 is not a through hole, the shavings 20B generated in the process of forming the screw hole 20 do not fly off outside. Since the potential of the tapping screw 21 and the heat sink 10 is the GND potential, a partial discharge caused by the shavings 20B is prevented.

While this disclosure is described in detail, the foregoing description is in all aspects illustrative and does not restrict the disclosure. Thus, numerous modifications that have yet been exemplified will be devised.

Embodiments of the present disclosure can be freely combined, and appropriately modified or omitted.

### EXPLANATION OF REFERENCE SIGNS

10 heat sink, 10A position defining portion, 10B side surface, 11 first region, 12 second region, 20 screw hole, 20B shavings, 21 tapping screw, 30 insulating substrate, 31 insulating layer, 32 circuit surface pattern, 33 heat dissipating surface pattern, 40 semiconductor element, 50 terminal, 60 metal wire, 70 case, 70A inner surface, 70B external surface, 71 protrusion, 72 defective portion, 80 sealant, 91 bonding material, 92 bonding material, 93 silicone adhesive, 101 to 103 semiconductor device, 105, 106 semiconductor device.

1. A semiconductor device, comprising:
a heat sink holding a semiconductor element; and
a case housing the semiconductor element held above the heat sink,
wherein a first screw hole is formed in a side surface of the heat sink,
a second screw hole in communication with the first screw hole is formed in the case, and
the case is fastened to the heat sink through a screw screwed into the first and second screw holes.

2. The semiconductor device according to claim 1,
wherein the screw is a tapping screw.

3. The semiconductor device according to claim 1,
wherein the heat sink includes a position defining portion that defines a position of the case in the heat sink,
the position defining portion includes a through hole penetrating an upper surface and a lower surface of the heat sink, or a cutout portion disposed in a periphery of the heat sink, and
the case mates with the position defining portion.

4. The semiconductor device according to claim 1,
wherein the heat sink is made of Cu, Al, or AlSiC.

5. The semiconductor device according to claim 1,
wherein the heat sink includes a first region made of AlSiC and a second region made of Al,
the first screw hole is formed in the second region, and
the screw is made of a material which is harder than Al and with which the first screw hole can be threaded when the screw is screwed into the first screw hole.

6. The semiconductor device according to claim 1,
wherein the case has a frame shape enclosing an upper surface of the heat sink in a plan view, and
the case is fastened to the side surface of the heat sink through the screw screwed from an external surface of the frame shape into the first and second screw holes.

7. The semiconductor device according to claim 1,
wherein the heat sink includes a space that can house shavings of the heat sink or the case, at a deepest portion of the first screw hole.

8. The semiconductor device according to claim 1,
wherein the semiconductor element is a power semiconductor element made of a wide bandgap semiconductor.

9. The semiconductor device according to claim 1,
wherein an end of the screw is located inside the screw hole formed in the heat sink.
